(19) United States
(12) Patent Application Publication
(10) Pub. No.: US 2024/0234211 A9
(43) Pub. Date: Jul. 11, 2024

(54) METHOD FOR MANUFACTURING A SEMICONDUCTOR DEVICE

(71) Applicant: SAMSUNG ELECTRONICS CO., LTD., Suwon-si (KR)

(72) Inventors: Keetae KIM, Suwon-si (KR); Seulgi YUN, Suwon-si (KR)

(21) Appl. No.: 18/239,191

(22) Filed: Aug. 29, 2023

(30) Foreign Application Priority Data
Oct. 20, 2022 (KR) 10-2022-0135476

(51) Int. Cl. H01L 21/8234; H01L 29/40

(52) U.S. Cl. CPC H01L 21/82345; H01L 21/823481; H01L 29/401

(57) ABSTRACT

A method of manufacturing a semiconductor device includes forming a gate insulation layer on a substrate having first and second regions. A first gate electrode layer is formed on the gate insulation layer in the first and second regions. A first sacrificial layer pattern is formed on the first gate electrode layer in the second region. A second gate electrode layer is formed on the first gate electrode layer in the first region and the first sacrificial layer pattern in the second region. The second gate electrode layer and the first sacrificial layer pattern in the second region are removed to form a first gate electrode including the gate insulation layer, the first gate electrode layer and the second gate electrode layers stacked on each other in the first region, and a second gate electrode including the first gate electrode layer on the gate insulation layer in the second region.

### CROSS-REFERENCE TO RELATED APPLICATION

This application claims priority under 35 U.S.C. § 119 to Korean Patent Application No. 10-2022-0135476, filed on Oct. 20, 2022 in the Korean Intellectual Property Office, the disclosure of which is incorporated by reference in its entirety herein.

### 1. TECHNICAL FIELD

Embodiments of the present disclosure relate to a method for manufacturing a semiconductor device. More particularly, embodiments of the present disclosure relate to a method for manufacturing a semiconductor device including transistors.

### 2. DISCUSSION OF RELATED ART

A semiconductor device may include transistors having various electrical characteristics. When an etching process for forming the transistors is performed, a gate insulation layer may be damaged due to the etching process. Therefore, the performance and reliability of the transistors may decrease.

### SUMMARY

Embodiments of the present disclosure provide a method fir manufacturing a semiconductor device including transistors.

According to an embodiment of the present disclosure, a method for manufacturing a semiconductor device includes etching a portion of a substrate having a first region and a second region to form active patterns and trenches between the active patterns. An isolation layer is filled in a lower portion of the trenches to form first active fins protruding from the isolation layer in the first region and second active fins protruding from the isolation layer in the second region. A gate insulation layer is formed on the first active fins, the second active fins, and the isolation layer. A first gate electrode layer is formed having metal on the gate insulation layer A first sacrificial layer pattern is formed on the first gate electrode layer in the second region. A second gate electrode layer is formed that includes a metal on the first gate electrode layer in the first region and the first sacrificial layer pattern in the second region. A first photoresist pattern is formed covering the second gate electrode layer in the first region. The second gate electrode layer is removed in the second region using the first photoresist pattern as an etching mask to form a second gate electrode pattern in the first region from the second gate electrode layer. The first sacrificial layer pattern is removed in the second region to form a first gate electrode including the gate insulation layer, the first gate electrode layer and the second gate electrode pattern stacked on each other in the first region and a second gate electrode including the first gate electrode layer disposed on the gate insulation layer in the second region.

According to an an embodiment of the present disclosure, a method for manufacturing a semiconductor device includes forming a gate insulation layer on a substrate having a first region, a second region, and a third region. A first gate electrode layer is formed having a first thickness on an entirety of an upper surface of the gate insulation layer. A first sacrificial layer pattern is formed on the first gate electrode layer in the first region. A second gate electrode layer is formed on the first sacrificial layer pattern in the first region and the first gate electrode layer in the second and third regions. The second gate electrode layer includes a same material as a material of the first gate electrode layer. A second sacrificial layer pattern is formed on the second gate electrode layer in the second region. A third gate electrode layer is formed on the second sacrificial layer pattern in the second region and the second gate electrode layer in the first and third regions. The third gate electrode layer includes the same material as the second gate electrode layer. A first photoresist pattern is formed covering the third gate electrode layer in the third region. The third gate electrode layer is removed in the first and second regions and the second gate electrode layer is removed in the first region. The first sacrificial layer pattern is removed in the first region and the second sacrificial layer pattern is removed in the second region to form a first gate electrode including the first gate electrode layer on the gate insulation layer in the first region, a second gate electrode including the gate insulation layer, the first gate electrode layer and the second gate electrode layers stacked on each other in the second region, and a third gate electrode including the gate insulation layer, the first gate electrode layer, the second gate electrode layer and the third gate electrode layers stacked on each other in the third region.

According to an embodiment of the present disclosure, a method for manufacturing a semiconductor device includes forming a gate insulation layer on a substrate having a first region and a second region. A first gate electrode layer is formed on the gate insulation layer in the first and second regions. A first sacrificial layer pattern is formed on the first gate electrode layer in the second region. A second gate electrode layer is formed on the first gate electrode layer in the first region and the first sacrificial layer pattern in the second region. A photoresist pattern is formed covering the second gate electrode layer in the first region. The second gate electrode layer and the first sacrificial layer pattern are removed in the second region to form a first gate electrode including the gate insulation layer, the first gate electrode layer and the second gate electrode layers stacked on each other in the first region, and a second gate electrode including the first gate electrode layer disposed on the gate insulation layer in the second region.

In embodiments of the present disclosure, damages of the gate insulation layer may be decreased. Therefore, the semiconductor device including transistors may be manufactured to have a high reliability.

### BRIEF DESCRIPTION OF THE DRAWINGS

Example embodiments will be more clearly understood from the following detailed description taken in conjunction with the accompanying drawings. FIGS. 1 to 33 represent non-limiting, example embodiments of the present disclosure as described herein.

FIGS. 1 to 22 are cross-sectional views and plan views illustrating a method of manufacturing a semiconductor device according to embodiments of the present disclosure; and

FIGS. 23 to 33 are cross-sectional views illustrating a method of manufacturing a semiconductor device according to embodiments of the present disclosure.

### DETAILED DESCRIPTION OF EMBODIMENTS

Hereinafter, preferred embodiments of the present invention will be described in detail with reference to the accompanying drawings.

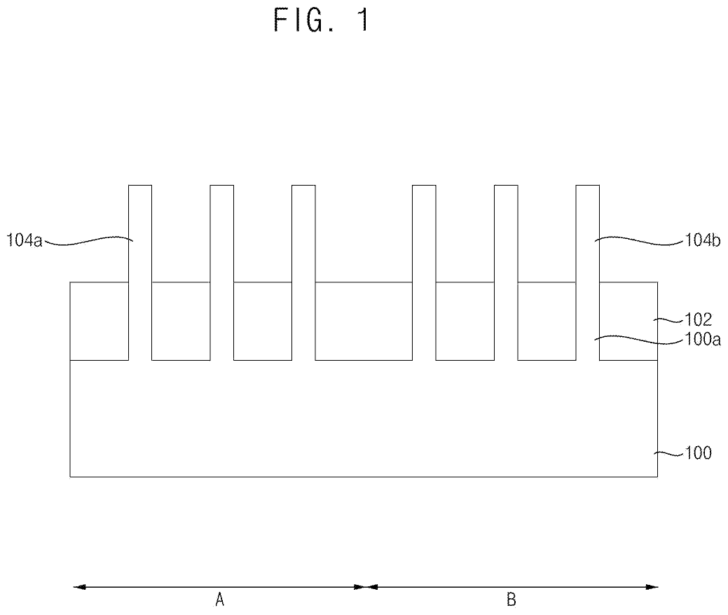

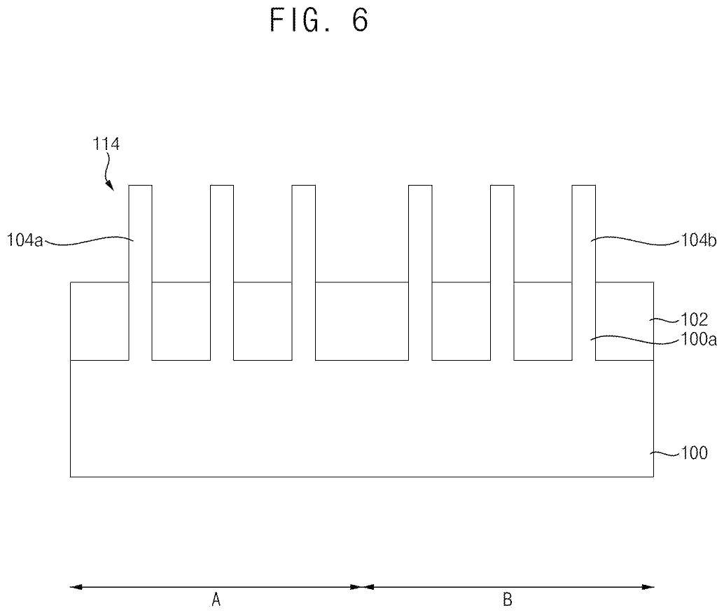

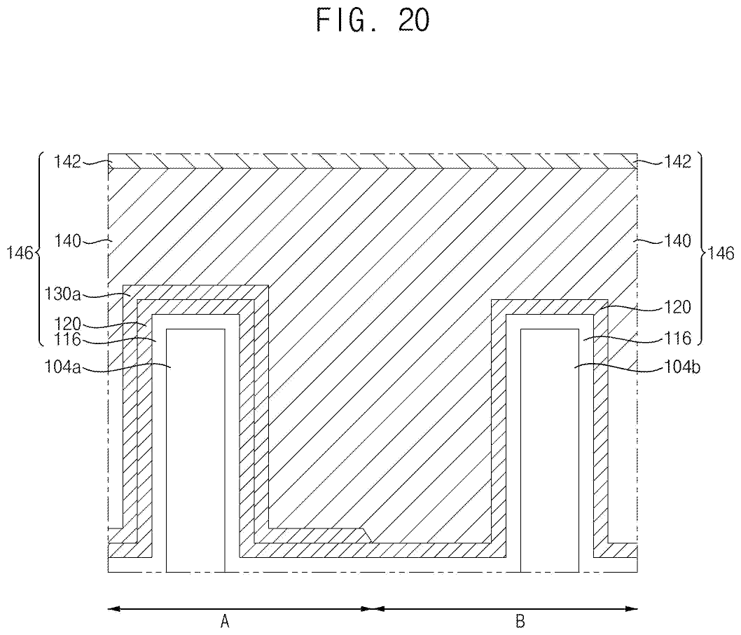

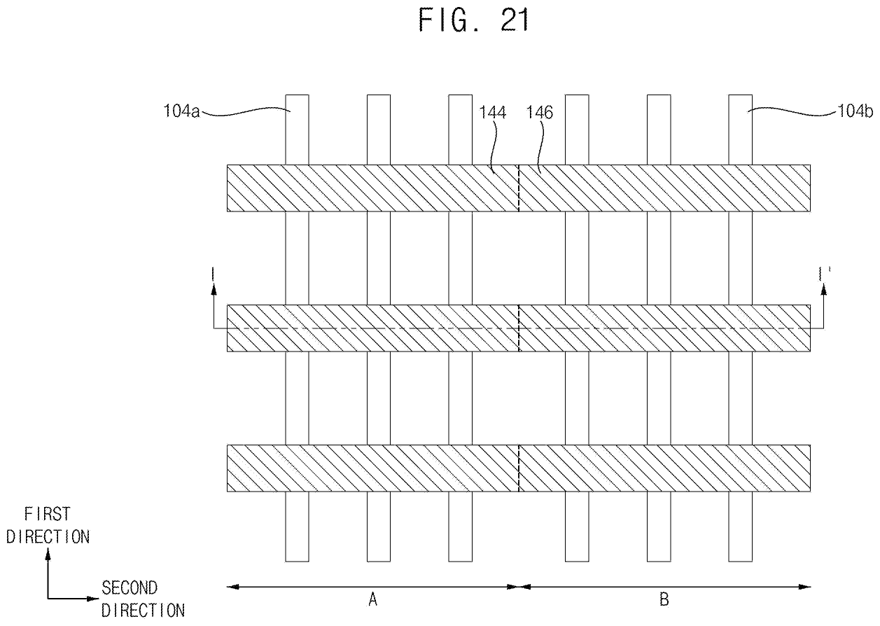

FIGS. 1 to 22 are cross-sectional views and plan views illustrating a method of manufacturing a semiconductor device according to embodiments of the present disclosure.

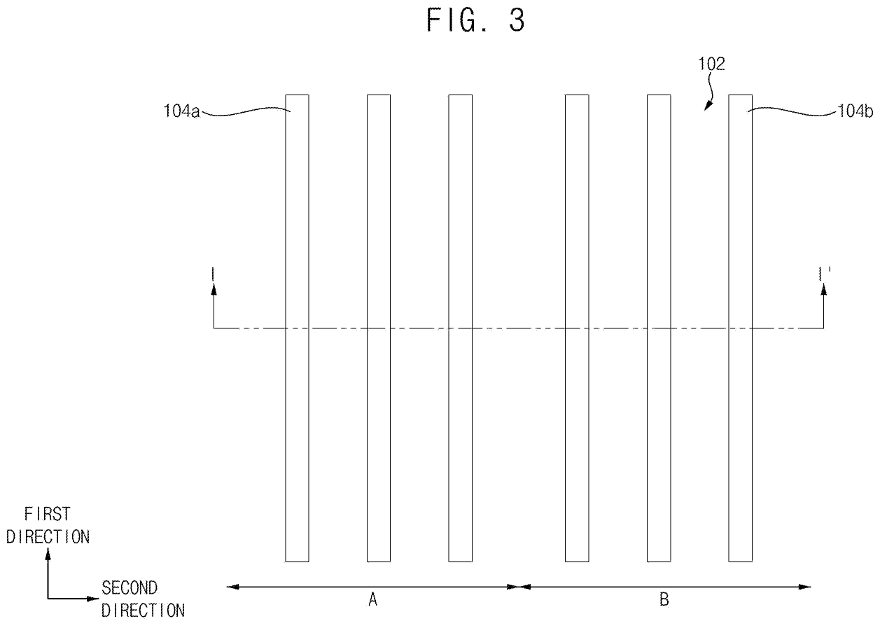

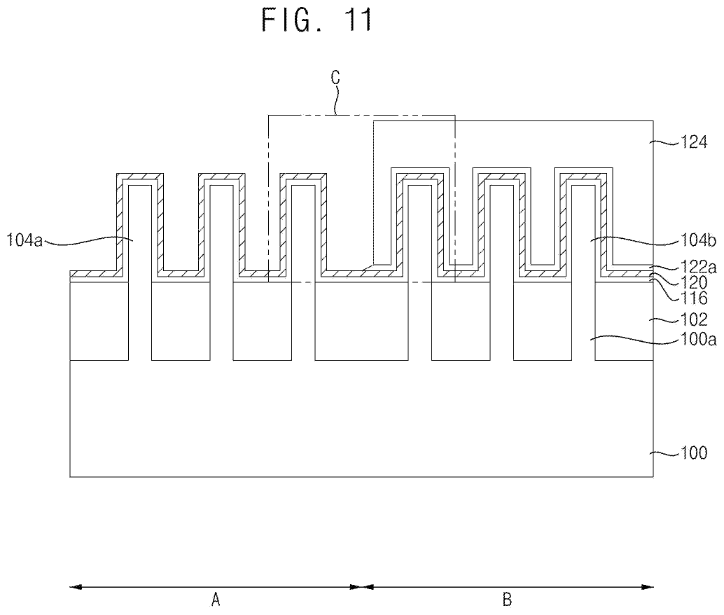

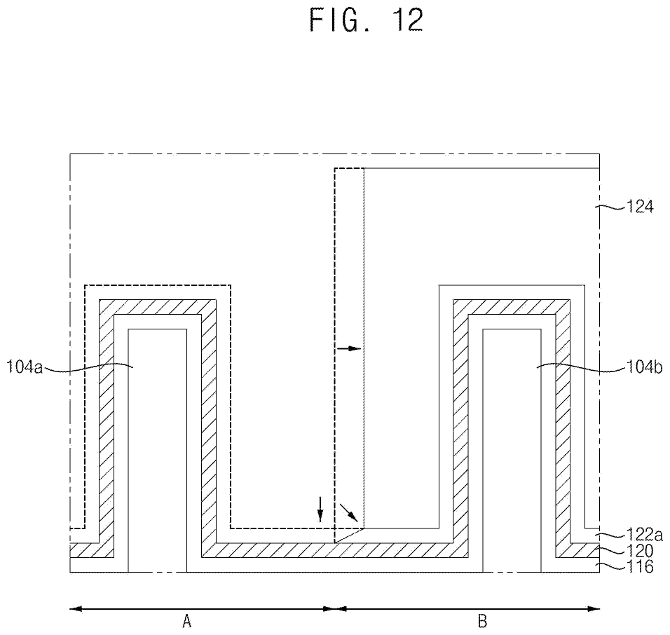

FIGS. 3, 5 and 21 are plan views. FIGS. 12, 16, 18 and 20 are enlarged views of portions C of FIGS. 11, 15, 17 and 19. FIGS. 1, 2, 4, 6 to 11, 13 to 15, 17, 19 and 22 are cross-sectional views taken along line I-I″ of each of plan views, respectively.

Referring to FIGS. 1 to 3, a substrate 100 may include a first region A for forming a first transistor and a second region B for forming a second transistor. In an embodiment, the first and second transistors may have different electrical characteristics from each other. The first and second transistors may have gate electrode layers directly contacting the gate insulation layer and having different thicknesses, respectively.

An upper portion of the substrate 100 may be anisotropically etched to form trenches. As the trenches may be formed on the substrate 100, active patterns 100a may be formed at the substrate 100 between the trenches. The active patterns 100a may extend in a first direction (FIG. 3), and may be spaced apart from each other in a second direction (FIG. 3) perpendicular to the first direction. However, embodiments of the present disclosure are not necessarily limited thereto and the first and second directions may cross each other at various different angles. An isolation layer 102 may be formed to fill a lower portion of the trenches.

In an embodiment, the substrate 100 may include a semiconductor material such as silicon, germanium, or silicon-germanium, or a III-V group semiconductor compound such as GaP, GaAs, or GaSb. In some embodiments, the substrate 100 may be a Silicon On Insulator (SOT) substrate or a Germanium On Insulator (GOD substrate. The substrate 100 may include a single-crystal semiconductor material, so that a material of the active pattern 100a may have single-crystallinity.

In an embodiment, an insulation layer may be formed on the substrate 100 to sufficiently fill the trenches. The insulation layer may be planarized until an upper surface of the active pattern 100a may be exposed, Thereafter, an upper portion of the insulation layer may be removed so as to expose an upper sidewall of the active pattern 100a to form the isolation layer 102. In an embodiment, the insulation layer may include an oxide such as silicon oxide. However, embodiments of the present disclosure are not necessarily limited thereto.

A portion of the active pattern 100a protruding from the isolation layer 102 may serve as an active fin.

In FIG. 1, three first active fins 104a extending in the first direction may be positioned in the first region A of the substrate 100, and three second active fins 104b extending in the first direction may be positioned in the second region B of the substrate 100. However, embodiments of the present disclosure are not necessarily limited thereto and the number of the first and second active fins 104a and 104b formed in the first and second regions A and B, respectively, may vary. For example, the number of each of first and second active fins 104a and 104b may be less than or greater than three.

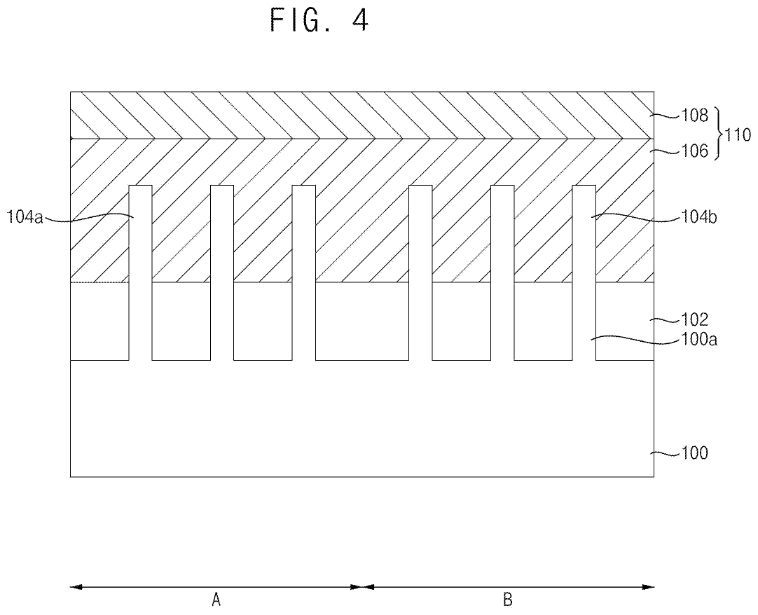

in FIG. 1, the first and second active fins formed by an ideal etching state without considering damage during the etching process may be shown, and the cross-sectional views of FIGS. 4 to 21 may be shown based on the cross-section of FIG. 1.

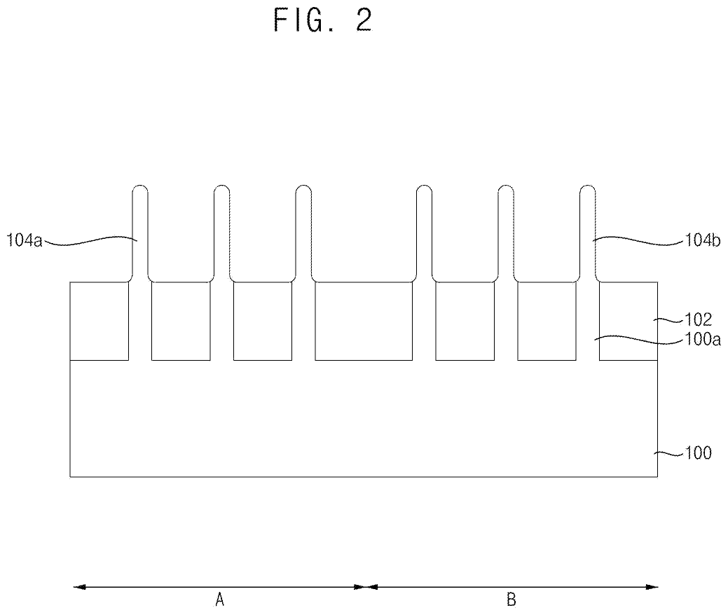

However, when the etching process is performed, as shown in FIG. 2, the upper surfaces of the first and second active tins 104a and 104b may be three-dimensionally etched to have a rounded shape. In addition, sidewalls of each of the first and second active fins 104a and 104h may be also partially etched, so that a width of each of the first and second active fins 104a and 104b may be less than a width of the active patterns 100a positioned below the first and second active fins 104a and 104b that are surrounded by the isolation layer 102.

In an embodiment, the first and second transistors formed on the first and second active fins 104a and 104b by subsequent processes may be fin field effect transistors (fin-FETs).

In some embodiments, the processes for forming the active fins on the substrate may not be performed. In these embodiments, an upper portion of the substrate may be anisotropically etched to form trenches, and an isolation layer 102 may be formed to completely fill the trenches. Therefore, the first and second transistors formed on the active patterns by subsequent processes may be planar type transistors.

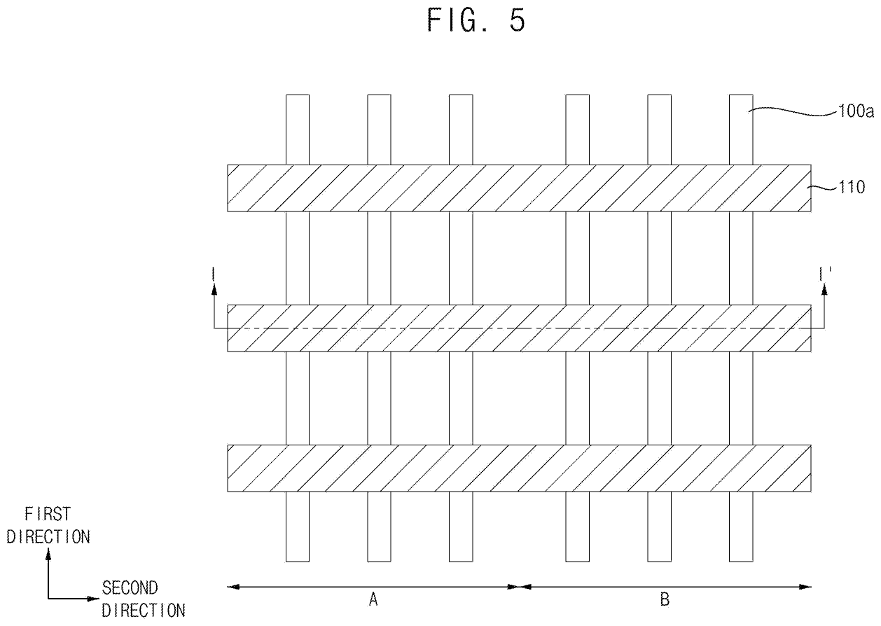

Referring to FIGS. 4 and 5, a dummy gate structure 110 in which a dummy gate insulation layer pattern, a dummy gate electrode 106 and a hard mask 108 are stacked may be formed on the first active fin 104a, the second active fin 104b and the isolation layer 102.

The dummy gate structure 110 may extend to cross the first and second active fins 104a and 104b. For example, in an embodiment the dummy gate structure 110 may extend in the second direction. A plurality of dummy gate structures 110 may be formed to be spaced apart from each other in the first direction.

In an embodiment, a spacer may be formed on sidewalls of the dummy gate structure 110. The spacer may include silicon nitride or a material having a dielectric constant (e.g., permittivity) lower than a dielectric constant of silicon nitride.

In an embodiment, a first impurity region may be formed in the first active fin 104a adjacent to both sides of the dummy gate structure 110. A second impurity region may be formed in the second active fin 104b adjacent to both sides of the dummy gate structure 110. The first impurity region may serve as a source/drain region of the first transistor, and the second impurity region may serve as a source/drain region of the second transistor.

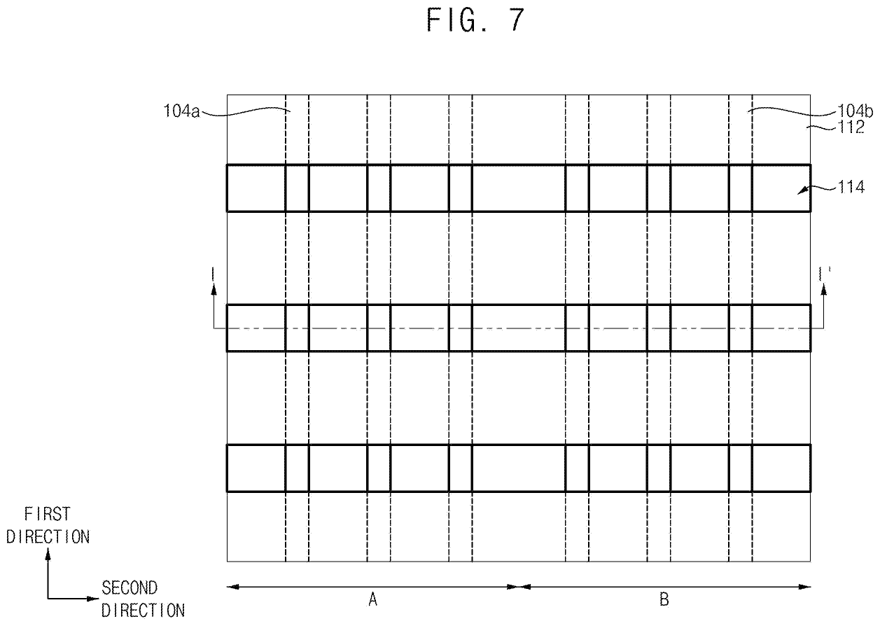

Referring to FIG. 7, a first insulating interlayer 112 may be formed on the first and second active fins 104a, 104b, isolation layer 102 and the dummy gate structure 110 to sufficiently fill gaps between the dummy gate structures 110. The first insulating interlayer 112 may be planarized until an upper surface of the dummy gate electrode 106 may be exposed. The hard mask 108 of the dummy gate structures 110 may be removed during the planarization process.

In an embodiment, the first insulating interlayer 112 may include silicon nitride or silicon oxide. However, embodiments of the present disclosure are not necessarily limited thereto. The first insulating interlayer 112 may be formed by a chemical vapor deposition process or an atomic layer deposition process.

The dummy gate electrode 106 and the dummy gate insulation layer pattern may be removed to form a first opening 114. The first and second active fins 104a and 104b and the isolation layer 102 may be exposed by the first opening 114. In an embodiment, an etching process for forming the first opening 114 may include wet etching process. The first opening 114 may extend in the second direction.

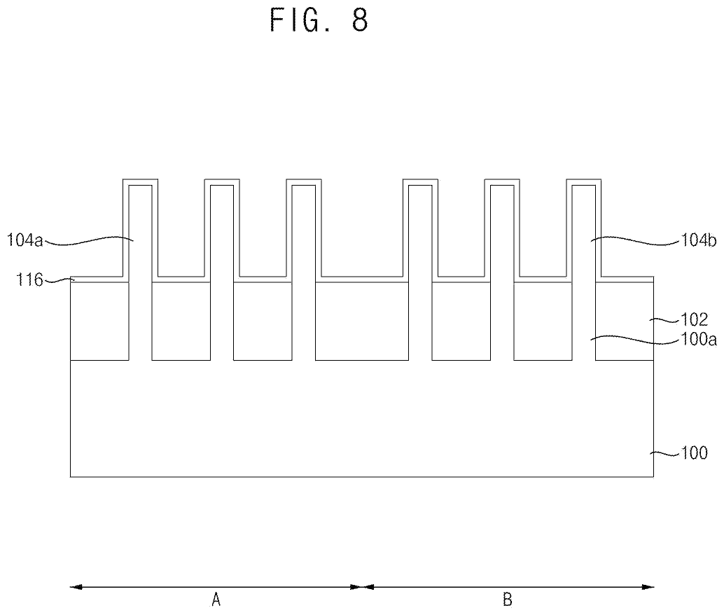

Referring to FIG. 8, a first insulation layer may be conformity formed on a surface of the first opening 114 and a surface of the first insulating interlayer 112. The first insulation layer may serve as a pad layer. In an embodiment, the first insulation layer may include silicon oxide. However, embodiments of the present disclosure are not necessarily limited thereto. The first insulation layer may be formed by an atomic layer deposition (ALD) process, a chemical vapor deposition (CVD) process, or a thermal oxidation process.

A gate insulation layer 116 may be formed on the first insulation layer and may conformally cover an upper surface of the isolation layer 102 and an upper surface and side surfaces of the first and second active fins 104a, 104b. The gate insulation layer 116 may include a metal oxide having a dielectric constant higher than a dielectric constant of silicon nitride. For example, in an embodiment the gate insulation layer 116 may include hafnium oxide (HfO₂), tantalum oxide (Ta2O5), or zirconium oxide (ZrO2). However, embodiments of the present disclosure are not necessarily limited thereto. The gate insulation layer 116 may be formed by a chemical vapor deposition process or an atomic layer deposition process.

In some embodiments, the gate insulation layer 116 may include a metal oxide doped with lanthanum (La). According to doping of the lanthanum in the metal oxide, electrical characteristics (e.g., threshold voltages) of the first and second transistors may be controlled.

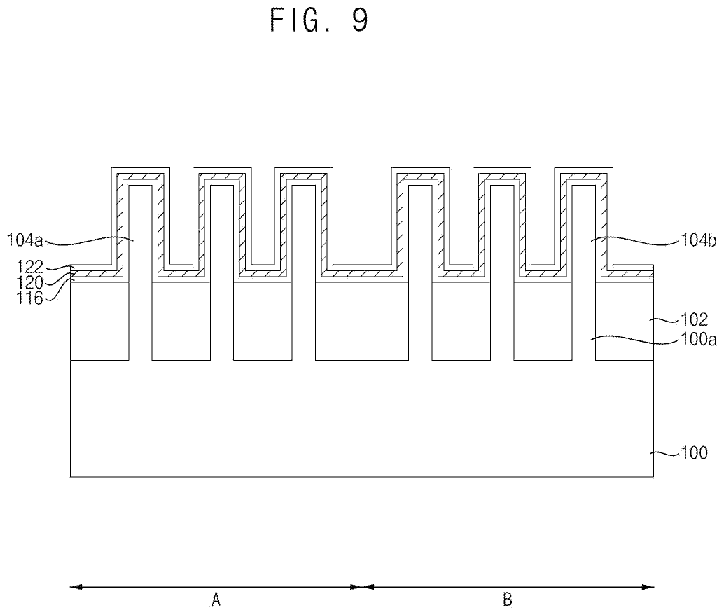

Referring to FIG. 9, a first gate electrode layer 120 may be formed along a surface of the gate insulation layer 116. The first gate electrode layer 120 may directly contact the surface of the gate insulation layer 116. The first gate electrode layer 120 may be conformally formed on the gate insulation layer 116.

The first gate electrode layer 120 may include a material in which characteristics of a transistor (e.g., threshold voltage) may be controlled according to a thickness of a layer. A work function of the first gate electrode layer 120 may vary depending on the thickness of the first gate electrode layer 120, and thus the threshold voltage of the transistor may be controlled by the thickness of the first gate electrode layer 120.

The first gate electrode layer 120 may serve as a capping layer for controlling (e.g., adjusting) the threshold voltage of the transistor and protecting the gate insulation layer 116. The first gate electrode layer 120 may include metal or metal nitride.

In an embodiment, the first gate electrode layer 120 may include at least one compound selected from titanium (Ti), titanium nitride (TiN), tantalum (Ta), tantalum nitride (TaN), or the like. For example, the first gate electrode layer 120 may include titanium nitride.

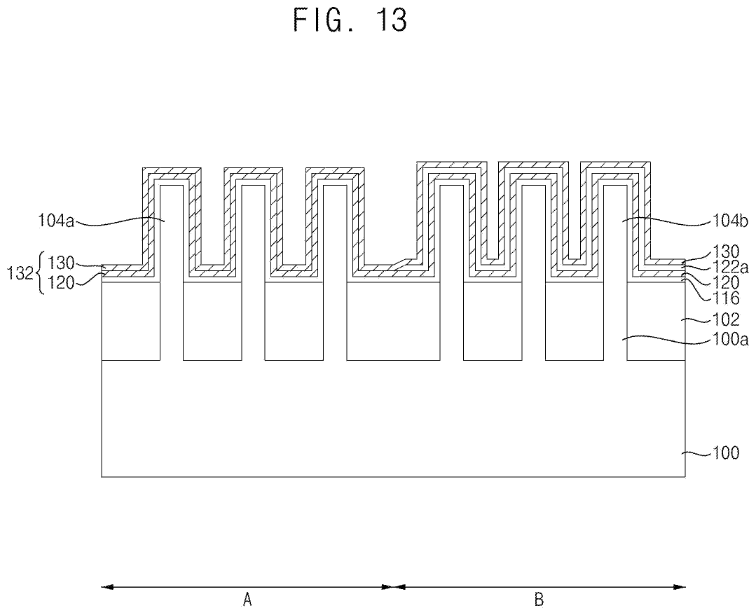

A first sacrificial layer 122 may be formed on the first gate electrode layer 120 to conformally cover the first gate electrode layer 120. The first sacrificial layer 122 may include a material that may be selectively etched with the first gate electrode layer 120. For example, the first sacrificial layer 122 may include a material having a high etching selectivity with respect to the first gate electrode layer 120. The first sacrificial layer 122 may also have a high etching selectivity with respect to the second gate electrode layer 130 (FIG. 13). The first sacrificial layer 122 may include a material that may be easily removed by a wet etching process.

In an embodiment, the first sacrificial layer 122 may include a metal oxide. For example, the first sacrificial layer 122 may include aluminum oxide.

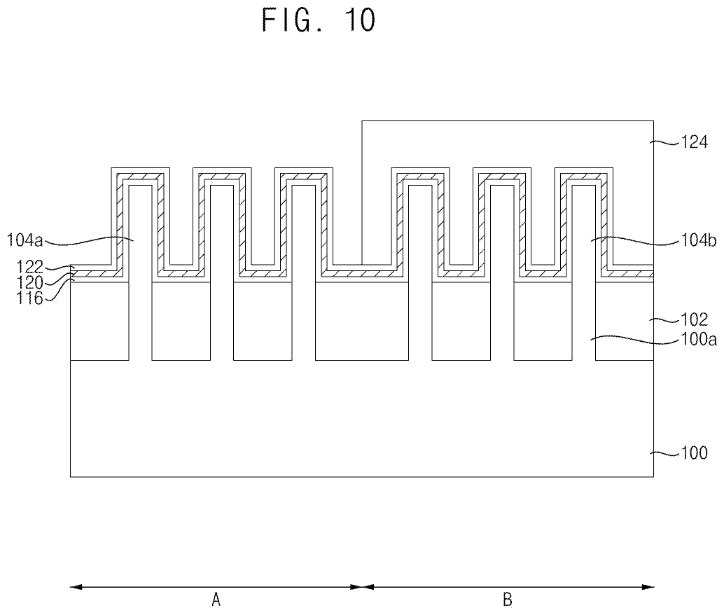

Referring to FIG. 10, a first photoresist pattern 124 may be formed on the first sacrificial layer 122 to cover the first sacrificial layer 122 in the second region B. For example, in an embodiment the first photoresist pattern 124 may cover an entirety of the first sacrificial layer 122 in the second region B. The first sacrificial layer 122 in the first region A may be selectively exposed by the first photoresist pattern 124.

Referring to FIGS. 11 and 12, in an embodiment the first sacrificial layer 122 in the first region A may be etched using the first photoresist pattern 124 as an etching mask to form a first sacrificial layer pattern 122a in the second region B.

In an embodiment, the etching process of the first sacrificial layer 122 may include a wet etching process, An etching damage of a layer formed under the first sacrificial layer 122 due to the wet etching process may be less than an etching damage of the layer formed under the first sacrificial layer 122 due to a dry etching process. In an embodiment in which the first sacrificial layer 122 is aluminum oxide, the first sacrificial layer 122 may be etched using, for example, ammonia water. In this embodiment, the first gate electrode layer 120 formed under the first sacrificial layer 122 may hardly be etched by the wet etching process. Accordingly, the first sacrificial layer pattern 122a may be formed from the first sacrificial layer in the second region B to selectively cover the first gate electrode layer 120 in the second region B.

As shown in FIG. 12, when the first sacrificial layer 122 is etched by the wet etching process, a sidewall portion of the first photoresist pattern 124 may be removed by a partial thickness. Accordingly, a portion of the first sacrificial layer 122 exposed by the first photoresist pattern 124 and a portion below a lower surface of an edge (e.g., a lateral edge) of the first photoresist pattern 124 may be etched by the wet etching process. The first sacrificial layer 122 positioned below the lower surface of the edge of the first photoresist pattern 124 may be etched to have a gentle slope. The edge of the first photoresist pattern 124 may be a boundary between the first and second regions A and B. Thus, the sidewall of the first sacrificial layer pattern 122a at the edge of the second region B may have a gentle slope.

During the wet etching process, the gate insulation layer 116 may be covered by the first gate electrode layer 120, and may not be exposed to an outside. Therefore, the gate insulation layer 116 may not be damaged or removed in the wet etching process. Consequently, deterioration of performance or defects of the transistor caused by damages to the gate insulation layer 116 may be decreased.

Referring to FIG. 13, a second gate electrode layer 130 may be formed on surfaces of the first sacrificial layer pattern 122a in the second region B and the first gate electrode layer 120 in the first region A, The second gate electrode layer 130 may conformally cover the first sacrificial layer pattern 122a in the second region B and the first gate electrode layer 120 in the first region A.

Accordingly, the first and second gate electrode layers 120 and 130 may be sequentially stacked on the gate insulation layer 116 in the first region A. The first gate electrode layer 120, the first sacrificial layer pattern 122a, and the second gate electrode layer 130 may be sequentially stacked on the gate insulation layer 116 in the second region B.

The second gate electrode layer 130 may include a material in which characteristics (e.g., a threshold voltage) of a transistor may be controlled according to a thickness of a layer. In an embodiment, the second gate electrode layer 130 may include the same material as the material of the first gate electrode layer 120. Accordingly, the first and second gate electrode layers 120 and 130 on the gate insulation layer 116 in the first region A may be merged into one to form a gate electrode layer structure 132.

An upper surface of the second gate electrode layer 130 in the first region A may be lower than an upper surface of the second gate electrode layer 130 in the second region B. The sidewall of the first sacrificial layer pattern 122a formed on the boundary between the first and second regions A and B may have the gentle slope, and thus the upper surface of the second gate structure layer 130 formed on the boundary between the first and second regions A and B may also have a gentle slope.

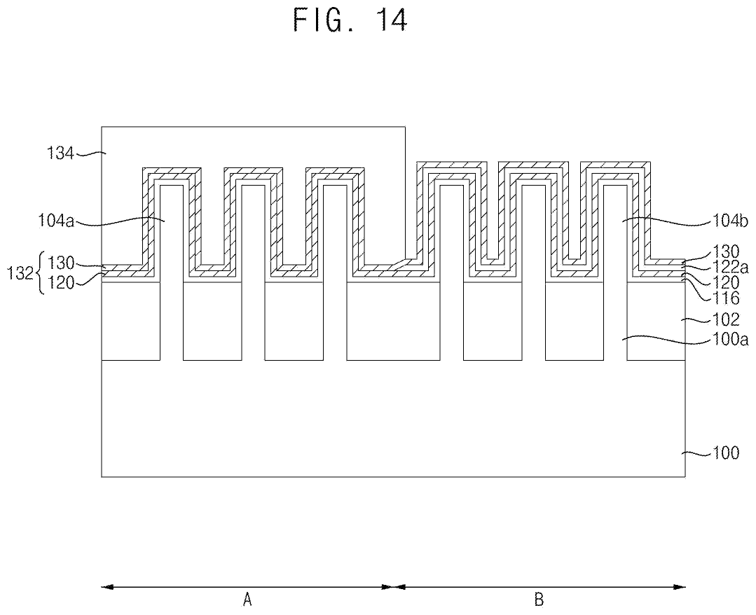

Referring to FIG. 14, a second photoresist pattern 134 may be formed on the second gate electrode layer 130 to cover the second gate electrode layer 131) in the first region A. For example, in an embodiment, the second photoresist pattern 134 may cover an entirety of the second gate electrode layer 130 in the first region A. In addition, the second photoresist pattern 134 may cover the upper surface of the second gate electrode layer 130 having the gentle slope formed on the boundary between the first and second regions A and B.

The second gate electrode layer 130 in the second region B may be exposed by the second photoresist pattern 134. For example, an entirety of the second gate electrode layer 130 in the second region B may be exposed by the second photoresist pattern 134.

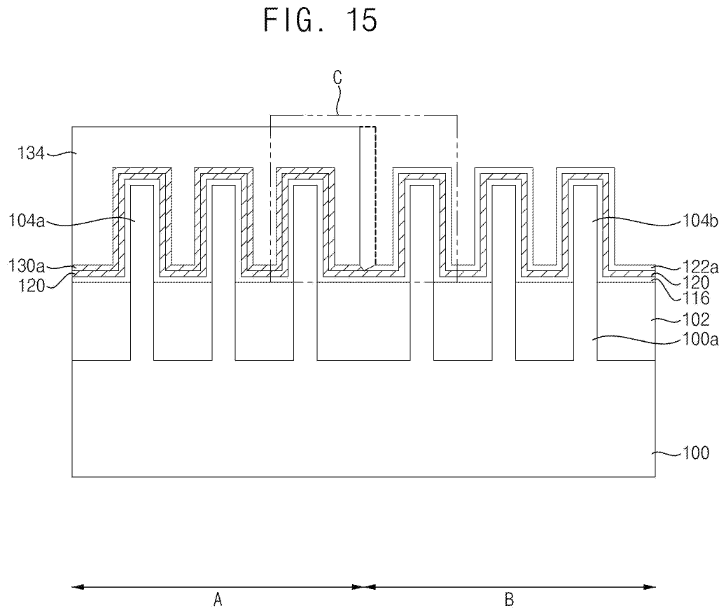

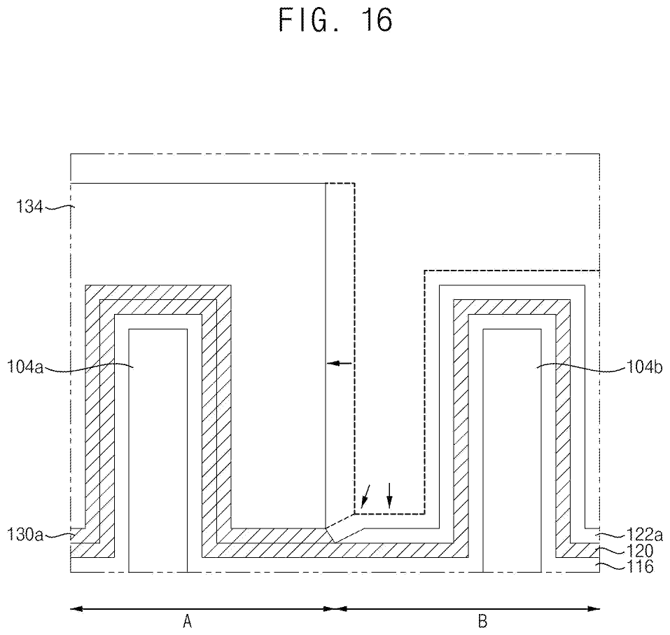

Referring to FIGS. 15 and 16, the second gate electrode layer 130 in the second region B may be etched using the second photoresist pattern 134 as an etching mask to form a second gate electrode pattern 130a.

The etching process of the second gate electrode layer 130 may include a wet etching process. For example, in an embodiment in which the second gate electrode layer 130 includes titanium nitride, hydrogen peroxide (H2O2) may be used as an etchant for etching of the second gate electrode layer 130. During the wet etching process, the gate insulation layer 116 may be covered by the first gate electrode layer 120, and may not be exposed to the outside. Therefore, the gate insulation layer 116 may not be damaged or removed in the wet etching process. Also, in the wet etching process, the first sacrificial layer pattern 122a may not be removed.

When the second gate electrode layer 130 is etched by the wet etching process, a sidewall portion of the second photoresist pattern 134 may be removed by a partial thickness. Accordingly, a portion of the second gate electrode layer 130 exposed by the second photoresist pattern 134 and a portion below a lower surface of an edge (e.g., a lateral edge) of the second photoresist pattern 134 may be etched by the wet etching process. The second gate electrode layer 130 positioned below the lower surface of the edge of the second photoresist pattern 134 may be etched by the wet etching process. In this embodiment, an upper surface of the second gate electrode layer 130 may be gradually etched from a high step portion to a low step portion, so that the sidewall of the second gate electrode pattern 130a formed after the etching may have a high slope with respect to the surface of the first gate electrode layer 120.

In an embodiment, the slope (based on an acute angle) of the sidewall of the second gate electrode pattern 130a with respect to the surface of the first gate electrode layer 120 may be greater than the slope (based on the acute angle) of the sidewall of the first sacrificial layer pattern 122a with respect to the surface of the first gate electrode layer 120. For example, in an embodiment the sidewall of the second gate electrode pattern 130a may have the slope (e.g., inclination) of about 45 degrees or more with respect to the surface (e.g., an upper surface) of the first gate electrode layer 120. Accordingly, a defect (e.g., a tail shape defect) in which the sidewall of the second gate electrode pattern 130a may have a gentle slope and an edge of the second gate electrode pattern 130a may laterally extend may be decreased.

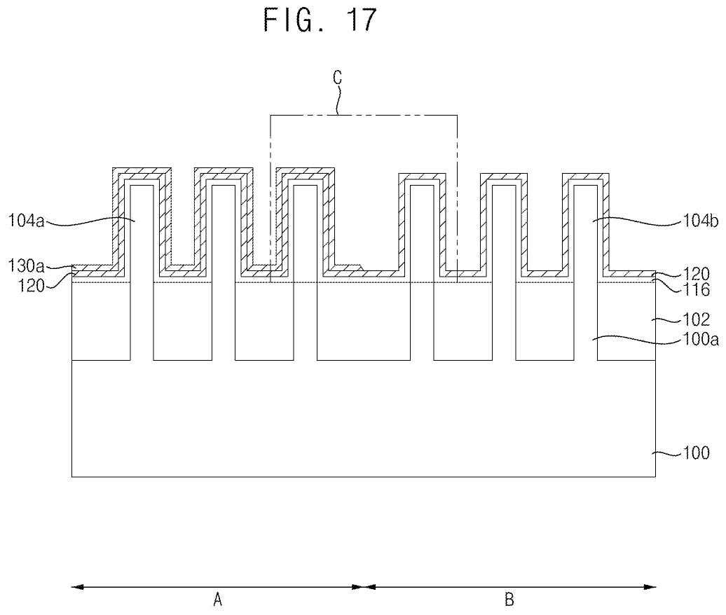

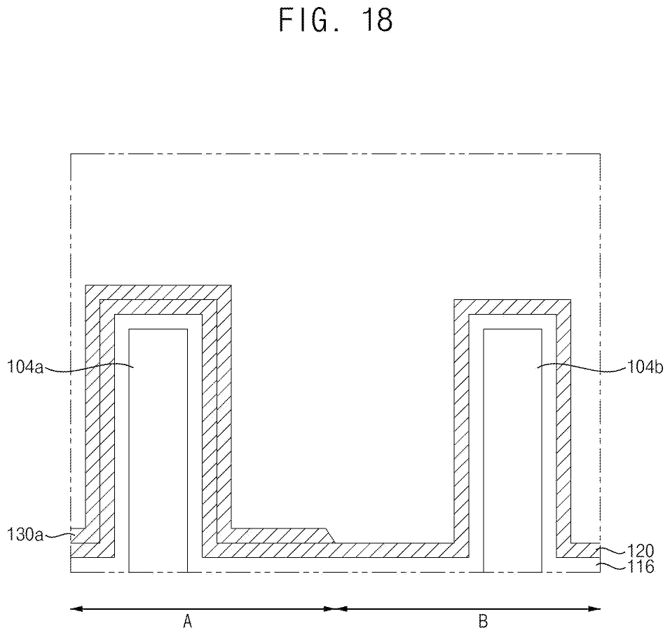

Referring to FIGS. 17 and 18, the first sacrificial layer pattern 122a may be removed by a wet etching process.

Accordingly, the first gate electrode layer 120 may be formed on the gate insulation layer 116 in the first and second regions A and B, and the second gate electrode pattern 130a may be formed on the first gate electrode layer 120 in the first region A from the second gate electrode layer 130.

For example, in an embodiment in which the first sacrificial layer pattern 122a is formed of aluminum oxide, the first sacrificial layer pattern 122a may be removed using ammonia water as an etchant.

The first gate electrode layer 120 may be formed on the gate insulation layer 116 in the first and second regions A and B, and the first gate electrode layer 120 in the first and second regions A and B may be contiguous with each other without being disconnected in the first and second regions A and B. The second gate electrode pattern 130a may be formed only on the first gate electrode layer 120 in the first region A and may not be disposed in the second region B.

During the wet etching process, the gate insulation layer 116 shay be covered by the first gate electrode layer 120, and may not be exposed to the outside. Therefore, the gate insulation layer 116 may not be damaged or removed in the wet etching process. Thus, deterioration of performance or defects of the transistor caused by damages of the gate insulation layer 116 may be decreased.

The first gate electrode layer 120 and the second gate electrode pattern 130a may be stacked (e.g., consecutively stacked) in the first region A. A stacked structure including the first gate electrode layer 120 and the second gate electrode pattern 130a may serve as a first gate electrode. The first gate electrode layer 120 in the second region B may serve as a second gate electrode. Therefore, a thickness of the first gate electrode formed in the first region A may be greater than a thickness of the second gate electrode formed in the second region B. As described above, the thicknesses of the first gate electrode in the first region A and the second gate electrode in the second region B may be different from each other. Thus, the first and second transistors formed in the first and second regions may have different electrical characteristics from each other.

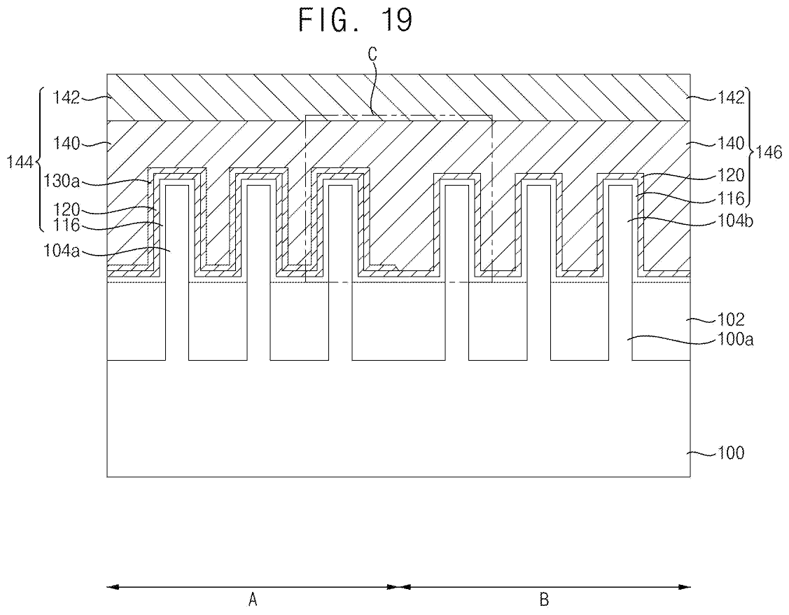

Referring to FIGS. 19 to 21, a conductive layer may be formed on the first gate electrode layer 120 and the second gate electrode pattern 130a to completely fill the first opening 114. In an embodiment, the conductive layer may include a metal or a metal nitride.

The conductive layer may be formed to decrease resistance. For example, in an embodiment, the conductive layer may include tungsten, aluminum (Al), copper (Cu), or the like.

Thereafter, the conductive layer, the first gate electrode layer 120 and the second gate electrode pattern 130a may be planarized until an upper surface of the first insulating interlayer may be exposed. Therefore, the conductive layer, the first gate electrode layer 120 and the second gate electrode pattern 130a may remain only in the first opening 114.

In addition, an upper portion of the conductive layer filling the first opening 114 may be etched to form a conductive layer pattern 140. A recess may be formed above the conductive layer pattern 140.

A hard mask layer may be formed to fill the recess. The hard mask layer may be planarized until the upper surface of the first insulating interlayer to form a hard mask 142. In an embodiment, the hard mask 142 may include silicon nitride or silicon oxynitride. However, embodiments of the present disclosure are not necessarily limited thereto.

Accordingly, a first gate structure 144 is formed in the first opening 114 of the first region A, and a second gate structure 146 is formed in the first opening 114 of the second region B.

The first gate structure 144 may have a structure in which the gate insulation layer 116, the first gate electrode layer 120, the second gate electrode pattern 130a, the conductive layer pattern 140, and the hard mask 142 are stacked (e.g., consecutively stacked). The second gate structure 146 may have a structure in which the gate insulation layer 116, the first gate electrode layer 120, the conductive layer pattern 140, and the hard mask 142 are stacked (e.g., consecutively stacked).

The first transistor on the first region A may include the first gate structure 144 and the first impurity region, and the second transistor on the second region B may include the second gate structure 146 and the second impurity region.

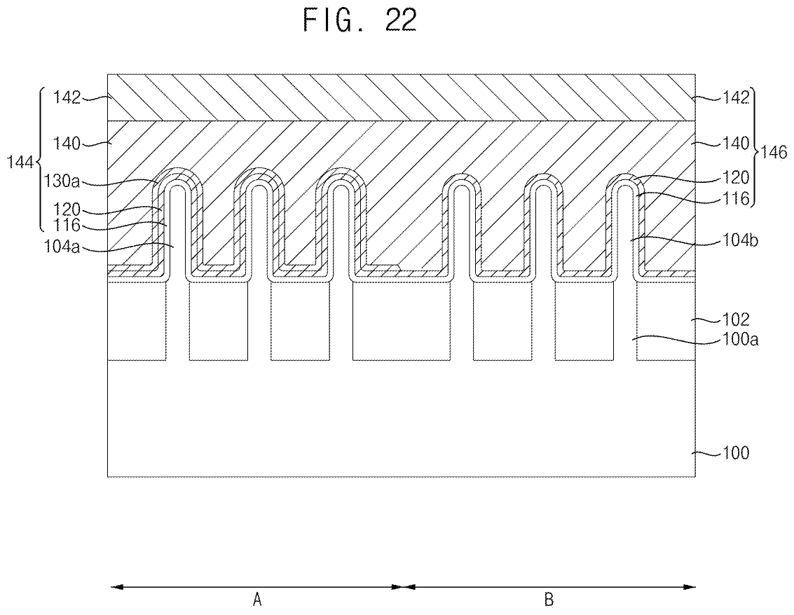

FIG. 22 illustrates first and second transistors formed on the first and second active fins shown in FIG. 2 by performing processes described with reference to FIGS. 4 to 21.

The semiconductor device formed by the above processes may have the following structure. Since most of structural features of the semiconductor device may be disclosed in method of manufacturing the semiconductor device, only main parts of the structural features may be described for economy of description.

Referring to FIGS. 19 to 21 again, trenches may be figured on the substrate 100 of the first region A and the second region B, and active patterns 100 between the trenches may protrude from bottoms of the trenches. The active patterns 100a may extend in the first direction, and may be spaced apart from each other in the second direction.

An isolation layer 102 may be formed in a lower portion of the trenches. Thus, the active patterns 100a may protrude from the isolation layer 102. A portion of each of the active patterns 100a protruding from the isolation layer 102 may serve as an active tin.

First active fins 104a protruding from the isolation layer 102 may be formed in the first region A of the substrate 100. Second active fins 104b protruding from the isolation layer 102 may be formed in the second region B of the substrate 100.

A first gate structure 144 extending in the second direction may be formed on the first active fins 104a and the isolation layer 102 in the first region A. A second gate structure 146 extending in the second direction may be formed on the second active fins 104b and the isolation layer 102 in the second region B.

The first gate structure 144 may have a structure in which a gate insulation layer 116, a first gate electrode layer 120, a second gate electrode pattern 130a, a conductive layer pattern 140 and a hard mask 142 are stacked (e.g., consecutively stacked). The second gate structure 146 may have a structure in which the gate insulation layer 116, the first gate electrode layer 120, the conductive layer pattern 140 and the hard mask 142 are stacked (e.g., consecutively stacked).

The first transistor formed on the first active fins 104a may have a first threshold voltage according to a thickness of a stacked structure including the first gate electrode layer 120 and the second gate electrode pattern 130a directly contacting the gate insulation layer 116. The second transistor formed on the second active fins 104h may have a second threshold voltage different from the first threshold voltage according to a thickness of the first gate electrode layer 120 directly contacting the gate insulation layer 116.

An edge (e.g., lateral edge) of the second gate electrode pattern 130a may be positioned at a boundary between the first and second gate structures 144 and 146 at a boundary of the first region A and the second region B, and a step difference between an upper surface the first gate electrode layer 120 and an upper surface of the second gate electrode pattern 130a may occur. In this embodiment, a sidewall of the second gate electrode pattern 130a may not be extended laterally. For example, in an embodiment a slope (based on an acute angle) of the sidewall of the second gate electrode pattern 130a with respect to the surface of the first gate electrode layer 120 may be, for example, about 45 degrees or more.

In addition, the first gate electrode layer 120 initially deposited on the gate insulation layer 116 may remain in the first and second gate structures 144 and 146. In etching processes for forming the first and second gate structures 144 and 146, the first gate electrode layer 120 may protect the gate insulation layer 116. Accordingly, etching damages of the gate insulation layer 116 included in the first and second gate structures 144 and 146 may be decreased, and thus the first and second transistors may have excellent electrical characteristics.

Hereinafter, a method for manufacturing transistors having various threshold voltage characteristics included in a semiconductor device may be described.

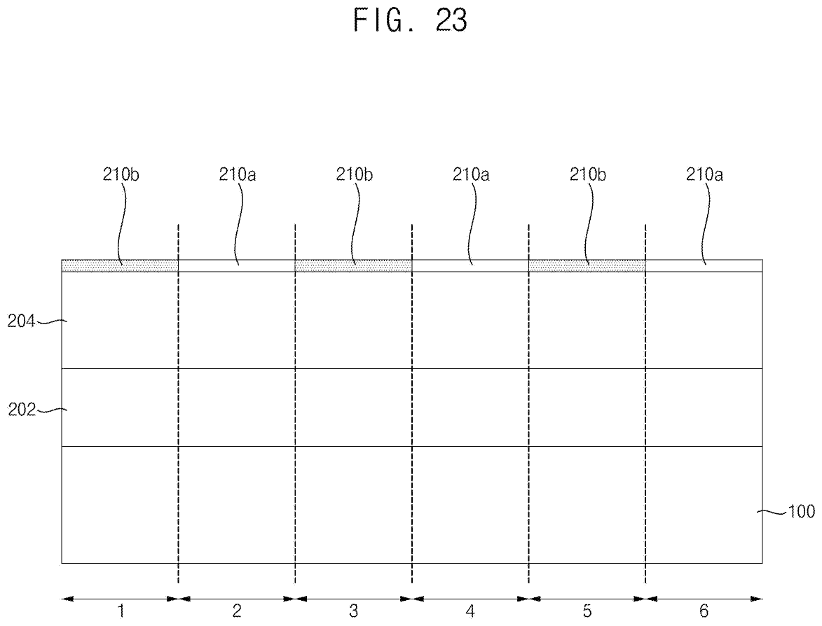

FIGS. 23 to 33 are cross-sectional views illustrating a method of manufacturing a semiconductor device according to embodiments of the present disclosure.

A semiconductor device may include six transistors having different characteristics. In each of the transistors, doping of gate insulation layers or a thicknesses of gate electrode layers may be different. In the manufacturing of the semiconductor device, processes fir forming gate electrode layers having different thicknesses may be mainly described. In each of cross-sectional views, processes for forming gate electrode layers on a top surface of an active fin in each of transistors may be illustrated. In FIGS. 23 to 33, the gate structures included in each of transistors may be adjacent to each other. However, embodiments of the present disclosure are not necessarily limited thereto and the gate structures may be spaced apart from each other.

Referring to FIG. 23, the substrate 100 may include first to sixth regions 1, 2, 3, 4, 5 and 6 in which first to sixth transistors having different electrical characteristics may be formed, respectively. The first and second regions 1 and 2 may be regions where a gate electrode layer having a first thickness may be formed. The third and fourth regions 3 and 4 may be regions in which a gate electrode layer having a second thickness greater than the first thickness may be formed. The fifth and sixth regions 5 and 6 are regions in which a gate electrode layer having a third thickness greater than the second thickness may be formed.

In an embodiment, an upper portion of the substrate 100 may be anisotropically etched to form trenches. As the trenches are formed on the substrate 100, active patterns may be formed between the trenches. An isolation layer 202 may be formed to fill a lower portion of the trenches. Thus, active fins 204 protruding from the isolation layer 202 may be formed.

Thereafter, the processes described with reference to embodiments of FIGS. 4 to 7 may be performed. Thus, the impurity region may be formed in the active fins 204. The first insulating interlayer may be formed on the active fins 204 and the isolation layer 202. The first insulating interlayer may include first openings at a region for forming the gate structures.

FIGS. 23 to 31 show layers formed on an uppermost surface of the active fin 204 exposed by the first opening in each of the first to sixth regions 1, 2, 3, 4, 5 and 6.

In an embodiment, a first insulation layer may be formed on the active fin 204. The first insulation layer may include silicon oxide.

A first gate insulation layer 210a may be conformally formed on the first insulation layer. In an embodiment, the first gate insulation layer 210a may include a metal oxide having a dielectric constant higher than dielectric constant of silicon nitride. For example, the first gate insulation layer 210a may include hafnium oxide (HfO2), tantalum oxide (Ta2O5), zirconium oxide (ZrO2), or the like. However, embodiments of the present disclosure are not necessarily limited thereto. The first gate insulation layer 210a may be formed by a chemical vapor deposition process or an atomic layer deposition process.

A portion of the first gate insulation layer 210a may be doped with lanthanum to form a second gate insulation layer 210b. In an embodiment, the first gate insulation layer 210a in the first, third and fifth regions 1, 3 and 5 may be doped with lanthanum. Accordingly, the second gate insulation layer 210b may be formed on the first insulation layer in the first, third and fifth regions 1, 3 and 5. The first gate insulation layer 210a may be formed on the first insulation layer in the second, fourth and sixth regions 2, 4 and 6.

A transistor including the first gate insulation layer 210a and a transistor including the second gate insulation layer 210h may have different electrical characteristics (e.g., threshold voltages) from each other. The second, fourth and sixth transistors may include the first gate insulation layer 210a, and the first, third and fifth transistors may include the second gate insulation layer 210h.

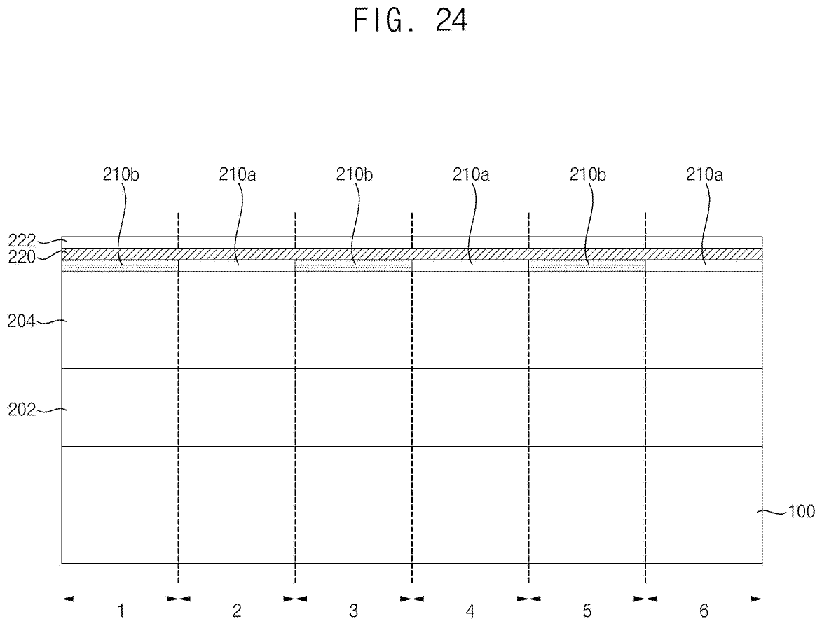

Referring to FIG. 24, a first gate electrode layer 220 may be formed along surfaces of the first and second gate insulation layers 210a and 210b. The first gate electrode layer 220 may directly contact surfaces of the first and second gate insulation layers 210a and 210b. The first gale electrode layer 220 may be conformally formed on the first and second gate insulation layers 210a and 210b.

The first gate electrode layer 220 may include a material in which characteristics of a transistor (e.g., a threshold voltage) may be controlled according to a thickness of a layer. The first gate electrode layer 220 may serve as a capping layer for controlling (e.g., adjusting) the threshold voltage of the transistor and protecting the first and second gate insulation layers 210a and 210b. In an embodiment, the first gate electrode layer 220 may include Ti, TiN, Ta, TaN, or the like. For example, the first gate electrode layer 220 may include TiN. However, embodiments of the present disclosure are not necessarily limited thereto.

The first gate electrode layer 220 may have the first thickness. For example, the first gate electrode layer 220 having a target (e.g., a predetermined, desired) first thickness may be formed in the first and second regions 1 and 2.

A first sacrificial layer 222 may be formed on (e.g., formed directly thereon) the first gate electrode layer 220. The first sacrificial layer 222 may include a material that may be selectively etched with the first gate electrode layer 220. For example, the first sacrificial layer 222 may include a material having a high etch selectivity with respect to the first gate electrode layer 220.

In an embodiment, the first sacrificial layer 222 may include a metal oxide. For example, the first sacrificial layer 222 may include aluminum oxide.

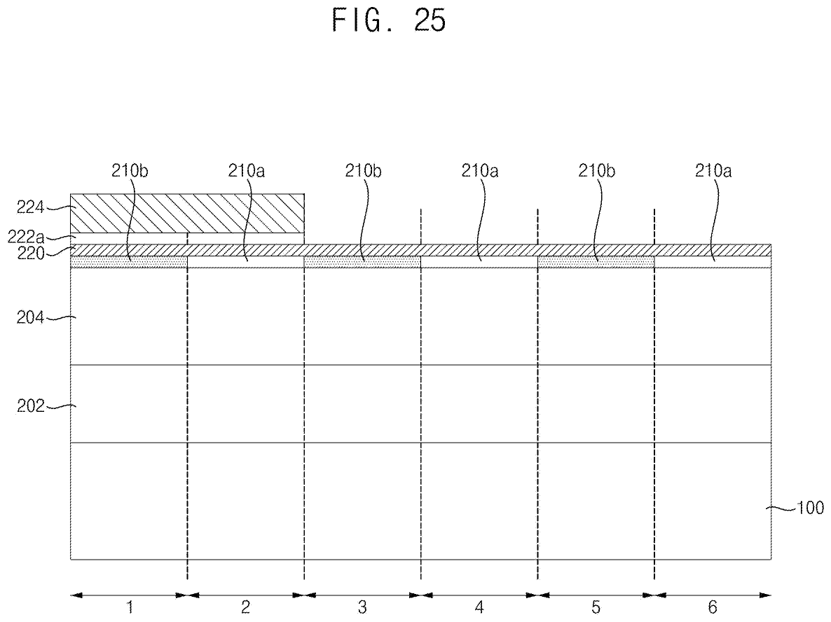

Referring to FIG. 25, a first photoresist pattern 224 may be formed to cover the first sacrificial layer 222 in the first and second regions 1 and 2. For example, as shown in an embodiment of FIG. 25, the first photoresist pattern 224 may cover an entirety of the first sacrificial layer in the first and second regions 1 and 2. The first sacrificial layer 222 in the third to sixth regions 3, 4, 5 and 6 may be exposed by the first photoresist pattern 224.

In an embodiment, the first sacrificial layer 222 in the third to sixth regions 3, 4, 5 and 6 may be etched using the first photoresist pattern 224 as an etching mask to form a first sacrificial layer pattern 222a. The first sacrificial layer pattern 222a may cover the first gate electrode layer 220 in the first and second regions 1 and 2.

The first gate electrode layer 220 having the target first thickness may be formed in the first and second regions 1 and 2. The first sacrificial layer pattern 222a may cover an upper surface of the first gate electrode layer 220 in the first and second regions 1 and 2.

During the etching process, the first and second gate insulation layers 210a and 210 may be covered by the first (gate electrode layer 220, and may not be exposed to outside. Therefore, in the etching process, the first and second gate insulation layers 210a and 210b may not be damaged or removed.

Thereafter, the first photoresist pattern 224 may be removed. Accordingly, the first sacrificial layer pattern 222a may be exposed in the first and second regions 1 and 2, and the first gate electrode layer 220 may be exposed in the third to sixth regions 3, 4, 5 and 6.

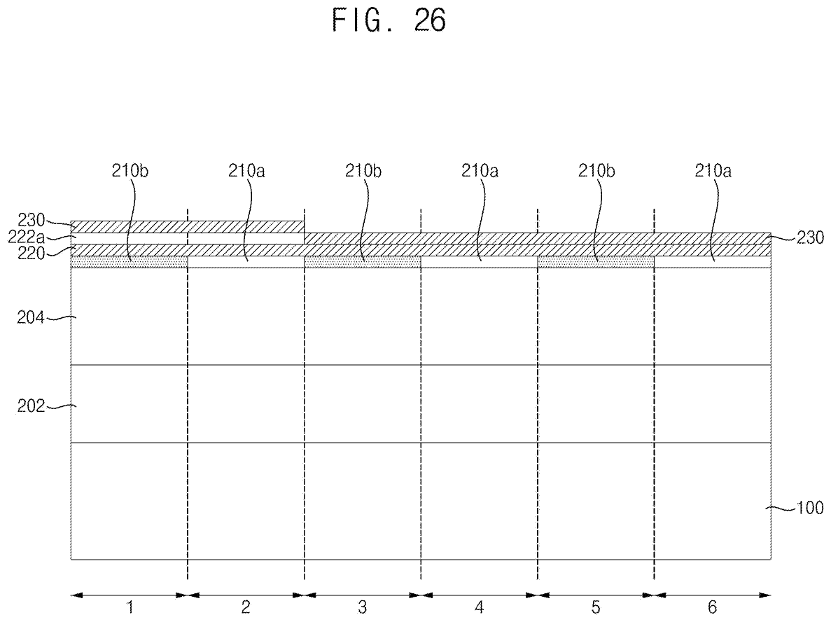

Referring to FIG. 26, a second gate electrode layer 230 may be firmed on surfaces of the first sacrificial layer pattern 222a and the first gate electrode layer 220.

Therefore, the first gate electrode layer 220, the first sacrificial layer pattern 222a, and the second gate electrode layer 230 may be sequentially stacked on the first and second gate insulation layers 210a and 210b in the first and second regions 1 and 2. The first gate electrode layer 220 and the second gate electrode layer 230 may be sequentially stacked on the first and second gate insulation layers 210a and 210b in the third to sixth regions 3, 4, 5 and 6.

The second gate electrode layer 230 may include a material in which characteristics (e.g., a threshold voltage) of the transistor may be controlled according to a thickness of a layer, in an embodiment, the second gate electrode layer 230 may include the same material as the material of the first gate electrode layer 220.

A stacked structure including the first and second gate electrode layers 220 and 230 may have the second thickness. For example, the stacked structure including the first and second gate electrode layers 220 and 230 having a second target thickness may be formed in the third and fourth regions 3 and 4.

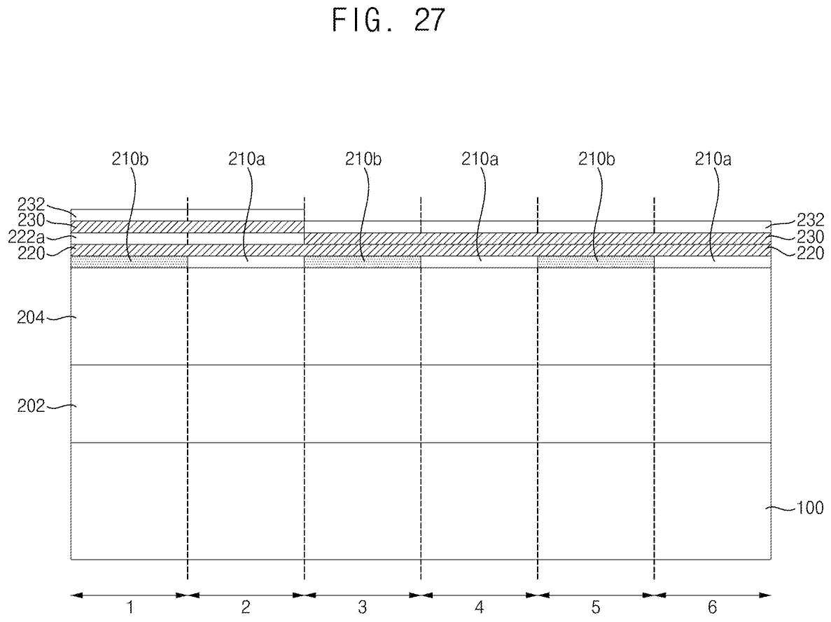

Referring to FIG. 27, a second sacrificial layer 232 may be formed on (e.g., formed directly thereon) the second gate electrode layer 230.

In an embodiment, the second sacrificial layer 232 may include a material having a high etching selectivity with respect to the second gate electrode layer 230. For example, in an embodiment the second sacrificial layer 232 may include the same material as the material of the first sacrificial layer pattern 222a. For example, the second sacrificial layer 232 may include aluminum oxide. However, embodiments of the present disclosure are not necessarily limited thereto.

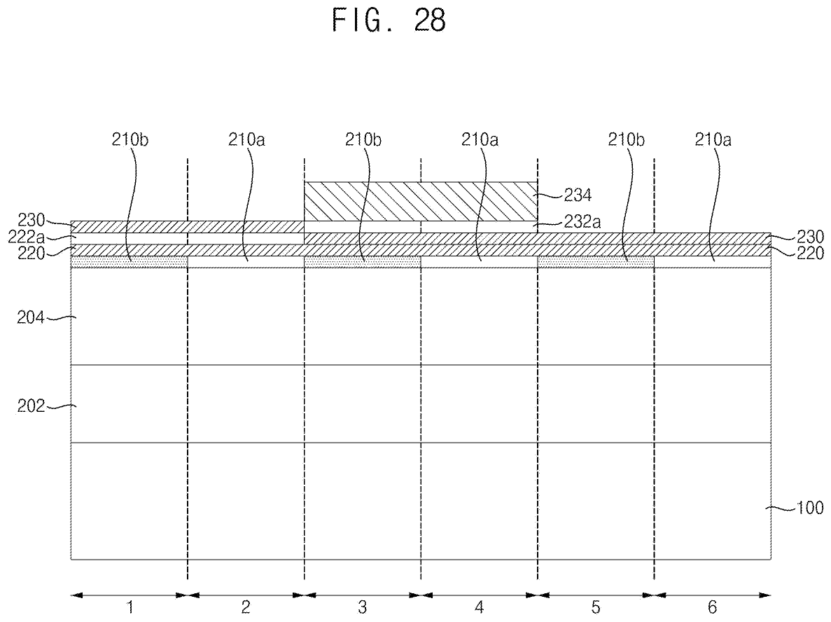

Referring to FIG. 28, a second photoresist pattern 234 may be formed to cover the second sacrificial layer 232 in the third and fourth regions 3 and 4. The second sacrificial layer 232 in the first and second regions 1 and 2 and the fifth and sixth regions 5 and 6 may be exposed by the second photoresist pattern 234.

The second sacrificial layer 232 may be etched using the second photoresist pattern 234 as an etching mask to form a second sacrificial layer pattern 232a. In an embodiment, the etching process of the second sacrificial layer 232 may include a wet etching process. In an embodiment in which the second sacrificial layer 232 is aluminum oxide, the second sacrificial layer 232 may be etched using ammonia water as an etchant.

Thereafter, the second photoresist pattern 234 may be removed, Accordingly, an upper surface of the second sacrificial layer pattern 232a may be exposed in the third and fourth regions 3 and 4. An upper surface of the second gate electrode layer 230 may be exposed in the first and second regions 1 and 2 and the fifth and sixth regions 5 and 6.

The stacked stricture including the first and second gate electrode layers 220 and 230 having the second target thickness may be formed in the third and fourth regions 3 and 4 as well as in the fifth and sixth regions 5 and 6. The second sacrificial layer pattern 232a may be formed to cover an upper surface of the second gate electrode layer 230 in the third and fourth regions 3 and 4.

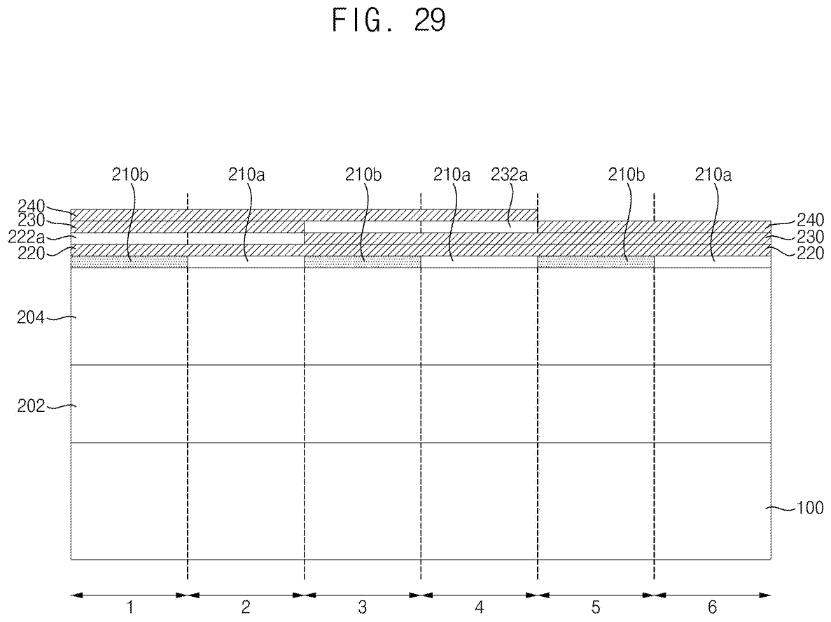

Referring to FIG. 29, a third gate electrode layer 240 may be formed on the second gate electrode layer 230 in the first and second regions 1 and 2 and the fifth and sixth regions 5 and 6 and the second sacrificial layer pattern 232a in the third and fourth regions 3 and 4.

Therefore, the first gate electrode layer 220, first sacrificial layer pattern 222a, and second and third gate electrode layers 230 and 240 may be sequentially stacked on the second gate insulation layers 210a and 210b in the first and second regions 1 and 2. The first and second gate electrode layers 220 and 230, second sacrificial layer patterns 232a and third gate electrode layers 240 may be sequentially stacked on the first and second gate insulation layers 210a and 210b in the third and fourth regions 3 and 4. The first, second and third gate electrode layers 220, 230 and 240 may be sequentially stacked on the first and second gate insulation layers 210a and 210b in the fifth and sixth regions 5 and 6.

In an embodiment, the third gate electrode layer 240 may include a material in which characteristics (e.g., a threshold voltage) of the transistor may be controlled according to a thickness of a layer. In an embodiment, the third gate electrode layer 240 may include the same material as the material of the second gate electrode layer 230.

A stacked structure including the first to third gate electrode layers 220, 230 and 240 may have the third thickness.

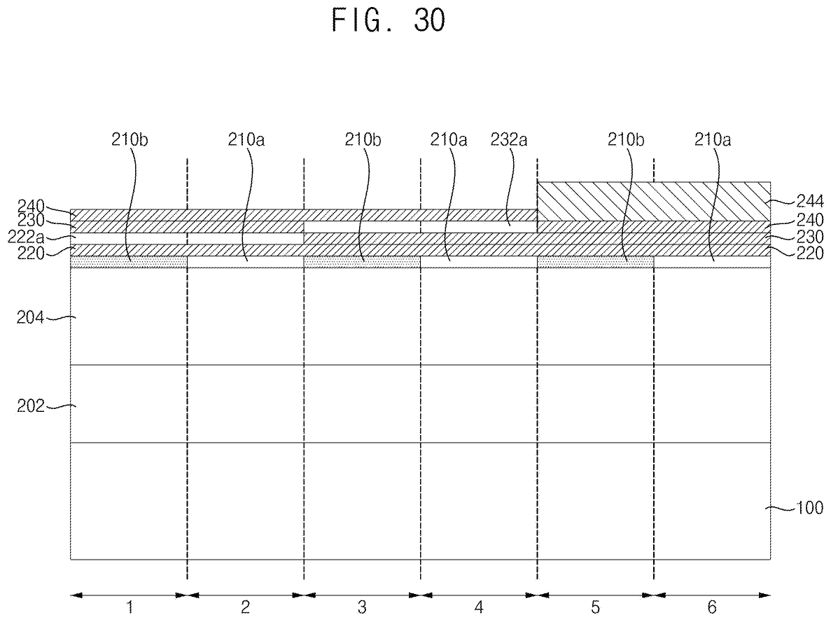

Referring to FIG. 30, a third photoresist pattern 244 may be formed to cover third gate electrode layer 240 in the fifth and sixth regions 5 and 6. The third gate electrode layer 240 in the first to fourth regions 1, 2, 3 and 4 may be exposed by the third photoresist pattern 244.

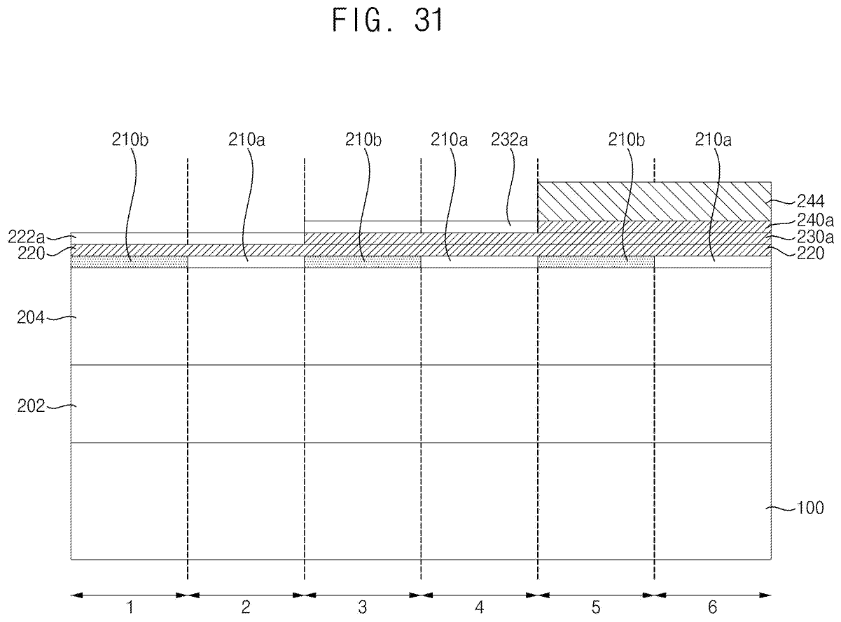

Referring to FIG. 31, the third gate electrode layer 240 in the first to fourth regions 1, 2, 3 and 4 may be etched using the third photoresist pattern 244 as an etching mask to form a third gate electrode pattern 240a in the fifth and sixth regions and 6. Subsequently, the second gate electrode layer 230 in the first and second regions 1 and 2 may be etched to form a second gate electrode pattern 230a in the third to sixth regions 3, 4, 5 and 6. Accordingly, the first sacrificial layer pattern 222a may be exposed in the first and second regions 1 and 2. The second sacrificial layer pattern 232a may be exposed in the third and fourth regions 3 and 4. In the etching process, the first and second sacrificial layer patterns 222a and 232a may hardly be etched. When the etching process is performed, the third gate electrode pattern 240a may be formed on the fifth and sixth regions 5 and 6. The second gate electrode pattern 230a may be formed on the third to sixth regions 3, 4, 5 and 6.

In an embodiment, the etching process of the third gate electrode layer 240 and the second gate electrode layer 230 may include wet etching process. For example, in an embodiment in which the second and third gate electrode layers 230 and 240 include titanium nitride, the second and third gate electrode layers 230 and 240 may be etched using hydrogen peroxide (H₂O₂) as an etchant.

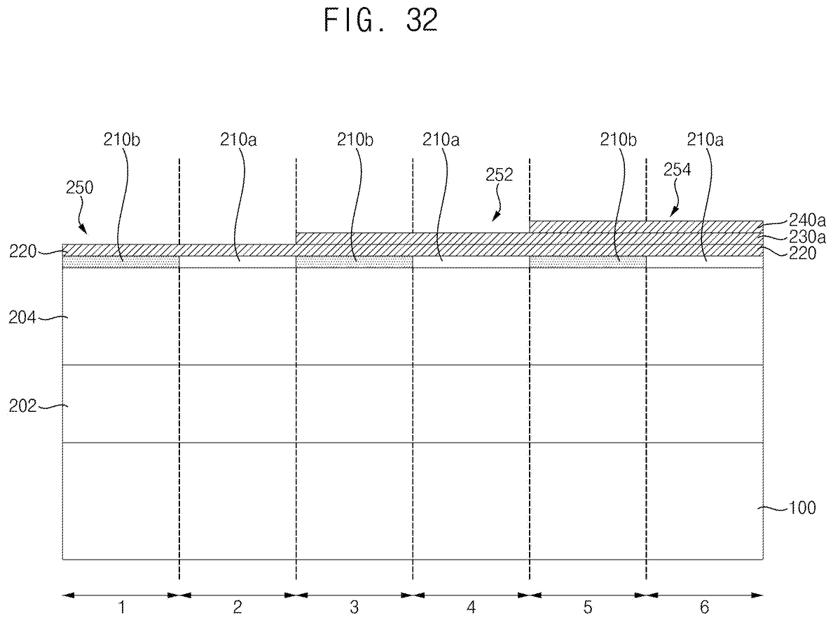

Referring to FIG. 32, the first sacrificial layer pattern 222a and the second sacrificial layer pattern 232a may be etched.

In an embodiment the etching process of the first sacrificial layer pattern 222a and the second sacrificial layer pattern 232a may include a wet etching process. In an embodiment in which the first sacrificial layer pattern 222a and the second sacrificial layer pattern 232a are aluminum oxide, the first sacrificial layer pattern 222a and the second sacrificial layer pattern 232a may be etched using, for example, ammonia water as an etchant.

Accordingly, the first gate electrode layer 220 may be exposed in the first and second regions 1 and 2. The second gate electrode pattern 230a may be exposed in the third and fourth regions 3 and 4, and the third gate electrode pattern 240a may be exposed in the fifth and sixth regions 5 and 6.

Thereafter, the third photoresist pattern 244 may be removed.

The first gate electrode layer 220 may be formed in the first and second regions 1 and 2 and may be exposed. The first gate electrode layer 220 and the second gate electrode pattern 230a may be stacked (e.g., consecutively stacked) in the third and fourth regions 3 and 4. A stacked structure including the first gate electrode layer 220 and the second gate electrode pattern 230a may serve as one gate electrode layer. The first gate electrode layer 220, the second gate electrode pattern 230a and the third gate electrode pattern 240a may be stacked in the fifth and sixth regions 5 and 6. A stacked structure including first gate electrode layer 220, second gate electrode pattern 230a, and third gate electrode pattern 240a may serve as one gate electrode layer.

As described above, a first gate electrode 250 having the first thickness and including the first gate electrode layer 220 may be formed in the first and second regions 1 and 2. A second gate electrode 252 having the second thickness and including the first gate electrode layer 220 and the second gate electrode pattern 230a may be formed in the third and fourth regions 3 and 4. A third gate electrode 254 having the third thickness and including the first gate electrode layer 220, the second gate electrode pattern 230a, and the third gate electrode pattern 240a may be formed in the fifth and sixth regions 5 and 6.

During a series of etching processes for forming the first to third gate electrodes 250, 252 and 254, the first and second gate insulation layers 210a and 210b may be covered by the first gate electrode layer 220, and may not be exposed to the outside. Therefore, in the etching process, the first and second gate insulation layers 210a and 210b may not be damaged or removed. Thus, defects of transistors caused by damages of the first and second gate insulation layers 210a and 210b may be decreased.

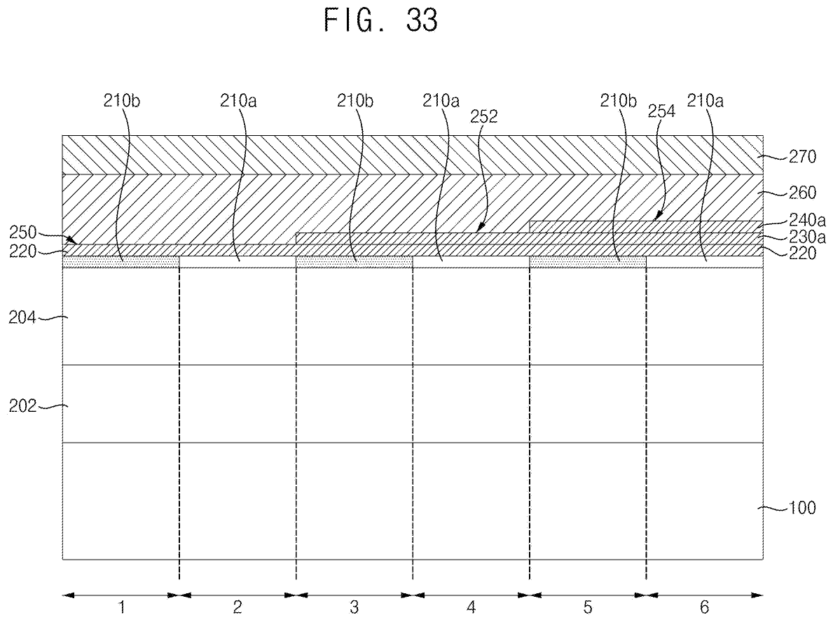

Referring to FIG. 33, a conductive layer pattern 260 and a hard mask 270 are formed on the first gate electrode layer 220, the second gate electrode pattern 230a and the third gate electrode pattern 240a.

In an embodiment, the conductive layer pattern 260 may include tungsten, aluminum (Al), copper (Cu), or the like.

Accordingly, first to sixth gate structures may be formed in the first openings in the first to sixth regions 1, 2, 3, 4, 5 and 6, respectively.

The first gate structure may have a structure in which the second gate insulation layer 210b, the first gate electrode layer 220, the conductive layer pattern 260 and the hard mask 270 are stacked (e.g., consecutively stacked). The second gate structure may have a structure in which the first gate insulation layer 210a, the first gate electrode layer 220, the conductive layer pattern 260 and the hard mask 270 are stacked (e.g., consecutively stacked), The third gate structure may have a structure in which the second gate insulation layer 210b, the first gate electrode layer 220, the second gate electrode pattern 230a, the conductive layer pattern 260 and the hard mask 270 are stacked (e.g., consecutively stacked). The fourth gate structure may have a structure in which the first gate insulation layer 210a, the first gate electrode layer 220, the second gate electrode pattern 230a, the conductive layer pattern 260 and the hard mask 270 are stacked (e.g., consecutively stacked). The fifth gate structure may have a structure in which the second gate insulation layer 210b, the first gate electrode layer 220, the second gate electrode pattern 230a, the third gate electrode pattern 240a, the conductive layer pattern 260 and the hard mask 270 are stacked (e.g., consecutively stacked). The sixth gate structure may have a structure in which the first gate insulation layer 210a, the first gate electrode layer 220, the second gate electrode pattern 230a, the third gate electrode pattern 240a, the conductive layer pattern 260 and the hard mask 270 are stacked (e.g., consecutively stacked).

First to sixth transistors may be formed in the first to sixth regions 1, 2, 3, 4, and 6, respectively. The first to sixth transistors may include the first to sixth gate structures, respectively. Stacked structures of the first to sixth gate structures may be different from each other, so that the first to sixth transistors may have different electrical characteristics from each other.

In the first to sixth gate structures, the first gate electrode layer 220 initially deposited on the first and second gate insulation layers 210a and 210b may remain without being removed. Accordingly, damages of the first and second gate insulation layers 210a and 210b included in the first to sixth gate structures may be decreased. Therefore, the first to sixth transistors may have excellent electrical characteristics.

The foregoing is illustrative of embodiments of the present disclosure and is not to be construed as limiting thereof. Although a few embodiments have been described, those skilled in the art will readily appreciate that many modifications are possible in embodiments without materially departing from the present disclosure. Accordingly, all such modifications are intended to be included within the scope of the present disclosure. Therefore, it is to be understood that the foregoing is illustrative of various example embodiments and the present disclosure is not to be construed as necessarily limited to the described embodiments.

What is claimed is:

1. A method for manufacturing a semiconductor device, comprising:
etching a portion of a substrate having a first region and a second region to form active patterns and trenches between the active patterns;
filling an isolation layer in a lower portion of the trenches to form first active fins protruding from the isolation layer in the first region and second active fins protruding from the isolation layer in the second region;
forming a gate insulation layer on the first active fins, the second active fins, and the isolation layer;
forming a first gate electrode layer having metal on the gate insulation laver;
forming a first sacrificial layer pattern on the first gate electrode layer in the second region;
forming a second gate electrode layer including a metal on the first gate electrode layer in the first region and the first sacrificial layer pattern in the second region;
forming a first photoresist pattern covering the second gate electrode layer in the first region;
removing the second gate electrode layer in the second region using the first photoresist pattern as an etching mask to form a second gate electrode pattern in the first region from the second gate electrode layer; and
removing the first sacrificial layer pattern in the second region to form a first gate electrode including the gate insulation layer, the first gate electrode layer and the second gate electrode pattern stacked on each other in the first region and a second gate electrode including the first gate electrode layer disposed on the gate insulation layer in the second region.

1. A method for manufacturing a semiconductor device, comprising:
etching a portion of a substrate having a first region and a second region to form active patterns and trenches between the active patterns;
filling an isolation layer in a lower portion of the trenches to form first active fins protruding from the isolation layer in the first region and second active fins protruding from the isolation layer in the second region;
forming a gate insulation layer on the first active fins, the second active fins, and the isolation layer;
forming a first gate electrode layer having metal on the gate insulation laver;
forming a first sacrificial layer pattern on the first gate electrode layer in the second region;
forming a second gate electrode layer including a metal on the first gate electrode layer in the first region and the first sacrificial layer pattern in the second region;
forming a first photoresist pattern covering the second gate electrode layer in the first region;
removing the second gate electrode layer in the second region using the first photoresist pattern as an etching mask to form a second gate electrode pattern in the first region from the second gate electrode layer; and
removing the first sacrificial layer pattern in the second region to form a first gate electrode including the gate insulation layer, the first gate electrode layer and the second gate electrode pattern stacked on each other in the first region and a second gate electrode including the first gate electrode layer disposed on the gate insulation layer in the second region.

2. The method of claim 1, wherein the gate insulation layer includes a metal oxide.

3. The method of claim 1, wherein the first and second gate electrode layers include a same material as each other.

4. The method of claim 1, wherein:
the removing of the second gate electrode layer includes a wet etching process; and
the removing of the first sacrificial layer pattern includes the wet etching process.

5. The method of claim 1, wherein each of the first and second gate electrode lavers includes at least one compound selected from titanium (Ti), titanium nitride (TiN), tantalum (Ta), or tantalum nitride (TaN).

6. The method of claim 5, wherein the removing of the second gate electrode layer include a wet etching process using hydrogen peroxide as an etchant.

7. The method of claim 1, wherein the first sacrificial layer pattern includes a material having an etch selectivity with respect to the first and second gate electrode lavers.

8. The method of claim 1, wherein the first sacrificial layer pattern includes aluminum oxide.

9. The method of claim 8, wherein the removing of the first sacrificial layer pattern includes a wet etching process using ammonia water as an etchant.

10. The method of claim 1, wherein forming a first sacrificial layer pattern on the first gate electrode layer in the second region comprises:
forming a first sacrificial layer on the first gate electrode layer;
forming a second photoresist pattern covering the first sacrificial layer in the second region; and
wet etching the first sacrificial layer in the first region using the second photoresist pattern as an etching mask to form the first sacrificial layer pattern from the first sacrificial layer in the second region,
wherein a sidewall of the first sacrificial layer pattern at a boundary between the first and second regions has a first slope with respect to an upper surface of the first gate electrode lager.

11. The method of claim 10, wherein the first photoresist pattern covers the second gate electrode layer in the first region and the second gate layer formed on the sidewall having the first slope of the first sacrificial layer pattern at the boundary between the first and second regions.

12. The method of claim 11, wherein a sidewall of the second gate electrode pattern at the boundary between the first and second regions has a second slope that is greater than the first slope with respect to an upper surface of the first gate electrode layer.

13. The method of claim 1, further comprising:
after the forming of the first and second active fins,
forming a dummy gate structure on the first and second active fins and the isolation layer;
forming an insulating interlayer covering the first and second active fins adjacent to both sides of the dummy gate structure; and
removing the dummy gate structure to form an opening in the insulating interlayer.

14. The method of claim 1, further comprising forming a conductive layer pattern and a hard mask on the first and second gate electrodes.

15. A method for manufacturing a semiconductor device, comprising:
forming a gate insulation layer on a substrate having a first region, a second region, and a third region;
forming a first gate electrode layer having a first thickness on an entirety of an upper surface of the gate insulation layer;
forming a first sacrificial layer pattern on the first gate electrode layer in the first region;
forming a second gate electrode layer on the first sacrificial layer pattern in the first region and the first gate electrode layer in the second and third regions, the second gate electrode layer including a same material as a material of the first gate electrode layer;
forming a second sacrificial layer pattern on the second gate electrode layer in the second region;
forming a third gate electrode layer on the second sacrificial layer pattern in the second region and the second gate electrode layer in the first and third regions, the third gate electrode layer including the same material as the second gate electrode layer;
forming a first photoresist pattern covering the third gate electrode layer in the third region;
removing the third gate electrode layer in the first and second regions and the second gate electrode layer in the first region; and
removing the first sacrificial layer pattern in the first region and the second sacrificial layer pattern in the second region to form a first gate electrode including the first gate electrode layer on the gate insulation layer in the first region, a second gate electrode including the gate insulation layer, the first gate electrode layer and the second gate electrode layers stacked on each other in the second region, and a third gate electrode including the gate insulation layer, the first gate electrode layer, the second gate electrode layer and the third gate electrode layers stacked on each other in the third region.

16. The method of claim 15, wherein the removing of the third gate electrode layer and the second electrode layer includes a wet etching process.

17. The method of claim 15, wherein the removing of the first and second sacrificial layer patterns includes a wet etching process.

18. The method of claim 15, wherein each of the first to third gate electrode layers includes at least one compound selected from titanium (Ti), titanium nitride (TiN), tantalum (Ta), or tantalum nitride (TaN).

19. The method of claim 15, wherein each of the first and second sacrificial layer patterns include aluminum oxide.

20. A method for manufacturing a semiconductor device, comprising:
forming a gate insulation layer on a substrate having a first region and a second region;
forming a first gate electrode layer on the gate insulation layer in the first and second regions;
forming a first sacrificial layer pattern on the first gate electrode layer in the second region;
forming a second gate electrode layer on the first gate electrode layer in the first region and the first sacrificial layer pattern in the second region;
forming a photoresist pattern covering the second gate electrode layer in the first region;
removing the second gate electrode layer and the first sacrificial layer pattern in the second region to form a first gate electrode including the gate insulation layer, the first gate electrode layer and the second gate electrode layers stacked on each other in the first region, and a second gate electrode including the first gate electrode layer disposed on the gate insulation layer in the second region.
